(19) United States
(12) Patent Application Publication
(10) Pub. No.: US 2005/0101043 A1
(43) Pub. Date: May 12, 2005

(54) Manufacturing method of image sensor device

(76) Inventors: Wei-Shiau Chen, Chin-Men Hsien (TW); Freddy Hsieh, Jhonghe City (TW)

Correspondence Address: J C PATENTS, INC., 4 VENTURE, SUITE 250, IRVINE, CA, 92618, US

(21) Appl. No.: 10/739,645

(22) Filed: Dec. 17, 2003

(30) Foreign Application Priority Data
Nov. 12, 2003 (TW) 92131626

(51) Int. Cl. H01L 21/00

(52) U.S. Cl. 438/30

(57) ABSTRACT

A manufacturing method of image sensor device is provided. The image sensor device is suitable for a substrate having at least one bonding pad. Wherein a plurality of photodiode sensing areas are formed on the substrate, at least a dielectric layer is formed over the substrate and the bonding pad is disposed in the dielectric layer. Wherein a first cover layer having an opening is disposed over the dielectric layer, wherein a portion of the bonding pad is exposed within the opening, forming a second cover layer over the first cover layer and the opening, and forming color filters over the second cover layer, then forming a planarization layer over the second cover layer and the color filters, and forming a plurality of micro lenses over the planarization layer.

### CROSS-REFERENCE TO RELATED APPLICATION

This application claims the priority benefit of Taiwan application serial no. 92131626, filed on Nov. 12, 2003, the full disclosure of which is incorporated herein by reference.

### BACKGROUND OF THE INVENTION

1. Field of the Invention

The present invention is generally related to a manufacturing method of an image sensor device. More particularly, the present invention relates to a manufacturing method of an image sensor device for preventing the generation of a pit on a surface of the bonding pad.

2. Description of the Related Art

Conventionally, a charge coupled device (CCD) is generally used for a solid-state image sensor since the property of high dynamic range, low dark current, and well developed technology. However, in recent years, since a complementary metal oxide semiconductor (CMOS) image sensor (CMOS Image Sensor, “CIS”) is substantially developed for being compatible with the manufacturing process of a CMOS transistor, and that can be easily integrated on a chip having another peripheral circuits, the cost and the power consumption of an image sensor can be reduced. Therefore, a CMOS image sensor is preferable to a CCD in a low cost image sensing application, and the importance of the CMOS transistor is enhanced by the CMOS image sensor.

In a solid-state image sensor device, such as a CCD and a CMOS image sensor described above, bonding pad is essential for electrically connecting with the external circuit. A voltage can be provided to the transistor of the image sensor device from the external circuit through the bonding pad in order to operate the image sensor device. Moreover, the electronic signal generated from the photoelectric conversion of the photodiode within the image sensor device is output to the external circuit through the bonding pad in order to convert the electronic signal into an image by a proper device.

FIG. 1A to FIG. 1D schematically illustrate a manufacturing method of a conventional image sensor device. Hereinafter, in order to simplify the description, parts of the components and the corresponding descriptions in the manufacturing process are omitted.

First of all, referring to FIG. 1A, a semiconductor silicon substrate 100 is provided, in which a plurality of photodiode sensing areas 102 are formed in the substrate 100. Next, a dielectric layer 104 having a bonding pad 106 is disposed on the substrate 100. Then, a cover layer 108 having an opening 110 is disposed on the surface of the dielectric layer 104 and the bonding pad 106, wherein a portion of the bonding pad 106 is exposed within the opening 110.

Referring to FIG. 1B, a plurality of color filters 112 are formed on the cover layer 108, wherein the color filters 112 are disposed over the photodiode sensing areas 102. The color filters 112 include three different colors (red, blue and green).

Referring to FIG. 1C, a planarization layer 114 is formed on the color filters 112 and the cover layer 108 in order to planarize the surfaces of the color filters 112.

Referring FIG. 1D, a photoresist layer is coated on the planarization layer 114, then the photoresist layer is exposed and developed to form a pattern on the photodiode sensing areas 102 corresponding color filters 112. Then a thermal process is performed, during which the photoresist pattern is transformed into a plurality of convex micro lenses 116. Thus, an image sensor is fabricated by the method describe above.

In the manufacturing process of an image sensor device described above, the cover layer 108 must be patterned to form the opening 110 to expose a portion of the bonding pad 106 before the color filters 112 and the micro lenses 116 are formed because the materials of the color filters 112 and the micro lenses 116 are photoresist materials. However, in the process of forming the color filters 112 and the micro lenses 116, the chemical solution of the photoresist and developer may react or etch the surface of the bonding pad 106, and thereby forming the pits 118 on the surface of the bonding pad 106. The existence of the pits 118 will adversely influence the wiring process of the package, and generally results in, for example, peeling of the wires, or poor electrical contact between the wires and the bonding pads.

### SUMMARY OF THE INVENTION

Accordingly, one object of the present invention is to provide a manufacturing method of an image sensor device, such that the surface of the bonding pad avoided from corrosion due to chemical solution of the photoresist and developer, so that a reliable wiring process can be carried out.

To achieve these and other advantages and in accordance with the purpose of the invention, as embodied and broadly described herein, a manufacturing method of an image sensor device is provided. The method is suitable for a substrate having at least one bonding pad, in which a plurality of photodiode sensing areas are formed in the substrate, and at least a dielectric layer is formed on the substrate. The bonding pad is disposed in the dielectric layer, in which a first cover layer having an opening is disposed on the dielectric layer, and the surface of the bonding pad is exposed within the opening. The method of the invention includes forming a second cover layer on the first cover layer and in the opening, then forming color filters on the second cover layer, and then forming a planarization layer on the second cover layer and color filters, finally forming a plurality of micro lenses on the planarization layer.

In accordance with a further object of the present invention, another manufacturing method of an image sensor device of the present invention is provided. The method is suitable for a substrate having at least one bonding pad, in which a plurality of photodiode sensing areas are formed in the substrate, at least a dielectric layer is formed on the substrate, and the bonding pad is disposed in the dielectric layer. The method of the invention includes forming a cover layer on the dielectric layer, then patterning the cover layer to form an opening in the cover layer over the surface of the bonding pad and retaining a portion of the cover layer in the opening for covering the surface of the bonding pad, and then forming a plurality of color filters on the cover layer, forming a planarization layer on the cover layer and the color filters, and finally forming a plurality of micro lenses on the planarization layer.

Moreover, in the manufacturing method of the image sensor device described above, further comprise removing the second cover layer of the surface of the bonding pad in the opening after forming the planarization layer on the second cover layer and the color filters, and before forming the micro lenses on the planarization layer.

Accordingly, because the surface of the bonding pad is covered by the covering layer during the process of forming the color filters and the micro lens, and therefore, the surface of the bonding pad is unaffected by the chemical solutions used during the process of forming the color filters and the micro lenses. Thus the surface of the bonding pad can be completely protected, and the wiring process can also be performed without any problems.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1D are cross-sectional views schematically illustrating a manufacturing process of a conventional image sensor device.

FIG. 2A to FIG. 2F are cross-sectional views schematically illustrating a manufacturing process of an image sensor device according to a preferred embodiment of the present invention.

FIG. 3A to FIG. 3F are cross-sectional views schematically illustrating a manufacturing process of another image sensor device according to another preferred embodiment of the present invention.

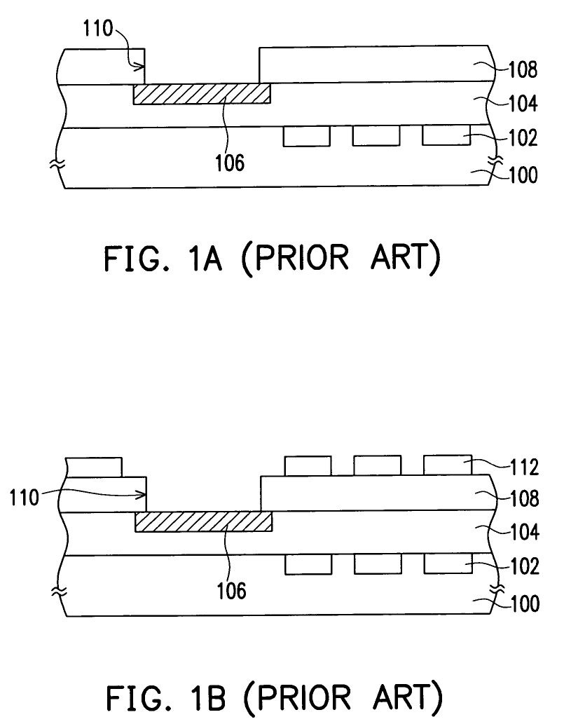

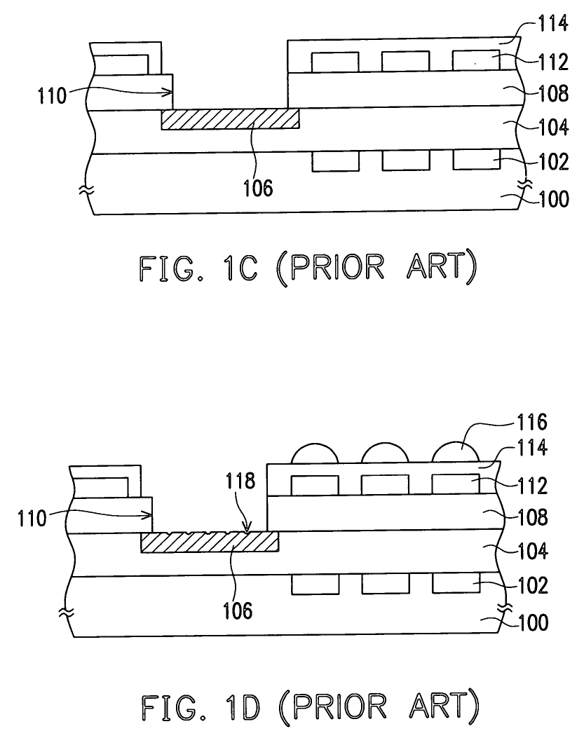

### DESCRIPTION OF THE PREFERRED EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

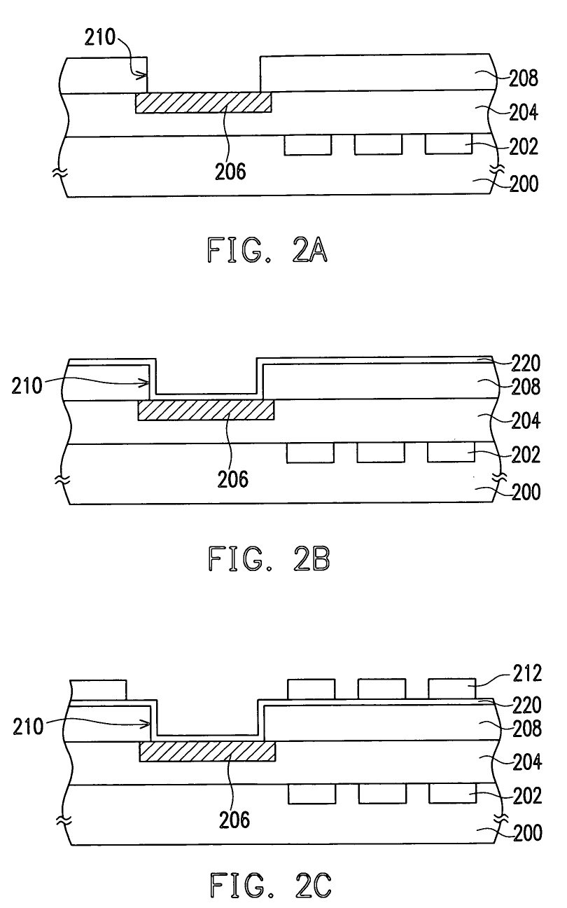

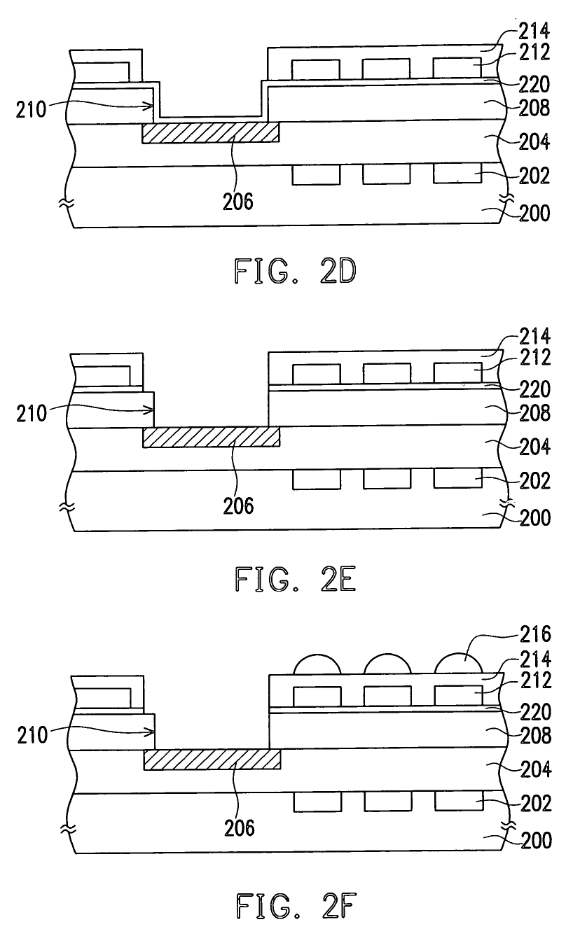

FIG. 2A to FIG. 2F are cross-sectional views schematically illustrating a manufacturing process of an image sensor device according to a preferred embodiment of the present invention. Hereinafter, in order to simplify the description, parts of the components and the corresponding descriptions in the manufacturing process are omitted.

First of all, referring to FIG. 2A, a substrate 200 is provided, and a plurality of photodiode sensing areas 202 is formed in the substrate 200. The photodiode sensing areas 202 are arranged into an array on the substrate 200. The array includes a plurality of patterns, and the patterns are also referred to as pixels.

Referring FIG. 2A, at least a dielectric layer 204 is formed on the substrate 200, and at least a bonding pad 206 is formed in the dielectric layer 204. A material of the bonding pad 206 includes, for example but not limited to, an aluminum metal. The bonding pad 206 is used for connecting with external circuit, in order to control the image sensor device.

Referring FIG. 2A, a patterned cover layer 208 is formed on the dielectric layer 204 and the surface of the bonding pad 206. The patterned cover layer 208 has an opening 210, wherein a portion of the bonding pad 206 is exposed within the opening 210. The material of the cover layer 208 includes, for example, but not limited to, a silicon nitride, and the method of forming cover layer 208 includes, for example, but not limited to, a chemical vapor deposition (CVD) method.

Next, referring FIG. 2B, a thin cover layer 220 is formed on the substrate 200 in order to cover the cover layer 208 and the opening 210. The material of the cover layer 220 includes, for example, but not limited to, a silicon oxide or a silicon nitride, and the method of forming the cover layer 220 includes, for example, but not limited to, a chemical vapor deposition (CVD) method. The thickness of the cover layer 220 is 30 nm.

Then, referring FIG. 2C, color filters 212 are formed on the cover layer 220 except for the opening 210, in which the color filters 212 include, for example, but not limited to, three different colors (red, blue and green). Moreover, the color filters 212 with different colors are disposed on different photodiode sensing areas 202. The method of forming the color filters 212 includes, for example, but not limited to, the following process. First of all, first color filters having a first color (for example, a red color) are forming using a conventional process. The first color filters are constituted with, for example, a dye of the first color (for example, a red color). Next, second color filters having a second color (for example, a blue color) are formed, wherein the second color filters are constituted with, for example, a dye of the second color (for example, a blue color). Finally, third color filters having a third color (for example, a green color) are formed, wherein the third color filters are constituted with, for example, a dye of the third color (for example, a green color).

Then, referring FIG. 2D, a planarization layer 214 is formed on the color filters 212 and the cover layer 220 in order to planarize the surface of the color filters 212, wherein the opening 210 and a portion of the cover layer 220 remain exposed. The material of the planarization layer 214 includes, for example, but not limited to, a transparent material such as a transparent polymer.

During the process of forming the color filters 212 and the planarization layer 214 described above, the surface of the bonding pad 206 is covered and protected by the cover layer 220. Therefore the surface of the bonding pad 206 is prevented from corosion or etching due to the chemical solution of the photoresist and developer during the process of forming the color filters 212 and the planarization layer 214.

Next, referring FIG. 2E, the cover layer 220 covering the opening 210 is removed in order to expose the surface of the bonding pad 206. The method of removing the cover layer 220 includes, for example, but not limited to, a dry etching method. It is to be noted that, since the process of removing the cover layer 220 is carried out after the forming the planarization layer 214, and therefore, damage to the color filters 212 during the removing process can be effectively avoided.

Moreover, preferably, the material of the above cover layer 220 is selected so as to be more easily removed during the removing process.

In addition, the advantage of the cover layer 220 being thin is that the cover layer 220 can be easily removed. Thus, the damage to the color filters 212 and the planarization layer 214 during the removal process can be substantially reduced or prevented.

Then, referring FIG. 2F, a plurality of micro lenses 216 are formed on the planarization layer 214, wherein the micro lenses 216 correspond to different color filters 212 respectively. The micro lenses 216 can focus and project the incident light of the image into the photodiode sensing areas 202 disposed on the surface of the image sensor device. The material of the micro lenses 216 includes, for example, but not limited to, a highly transparent photoresist material, such as a positive photoresist. The method of forming the micro lenses 216 includes, for example, but not limited to the following steps. The above photoresist material is on the planarization layer 214. Next, an exposure and development processes are carried out to form photoresist patterns over each of the pixels, i.e., the photodiode sensing areas 202. Next, a thermal process is performed to transform the photoresist patterns into convex micro lenses 216 having a focusing function. Thus, an image sensor device of the present invention can be fabricated by using the above process.

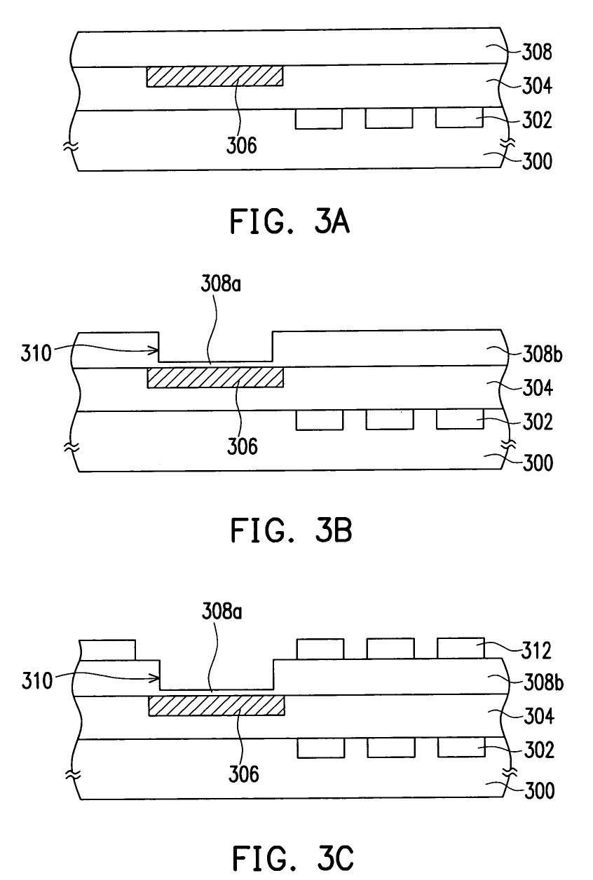

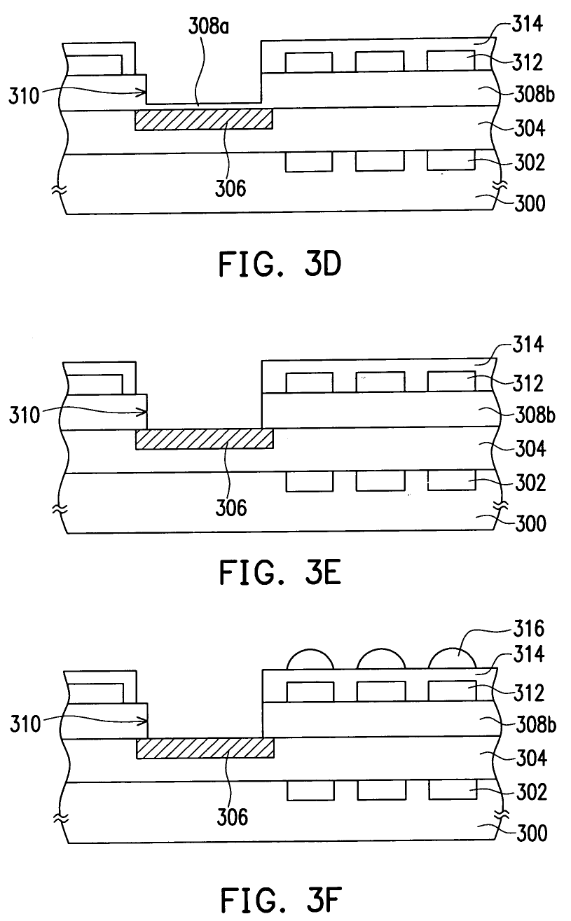

FIG. 3A to FIG. 3F are cross-sectional views schematically illustrating a manufacturing process of an image sensor device according to another preferred embodiment of the present invention. Hereinafter, in order to simplify the description, parts of the components and the corresponding descriptions in the manufacturing process are omitted.

First of all, referring to FIG. 3A, a substrate 300 is provided, and a plurality of photodiode sensing areas 302 is formed in the substrate 300. The photodiode sensing areas 302 are arranged into an array on the substrate 300. The array includes a plurality of patterns, and the patterns are also referred to as pixels.

Referring FIG. 3A, at least a dielectric layer 304 is formed on the substrate 300, and at least a bonding pad 306 is formed in the dielectric layer 304. Next, a cover layer 308 is formed on the dielectric layer 304 and the surface of the bonding pad 306. The material of the cover layer 308 includes, for example, but not limited to, a silicon nitride, and the method of forming cover layer 308 includes, for example, but not limited to, a chemical vapor deposition (CVD) method.

Next, referring FIG. 3B, the cover layer 308 is patterned in order to form a cover layer 308b having an opening 310, in which the opening 310 is formed over the bonding pad 306. A thin cover layer 308a is formed in the opening 310 to completely cover the surface of the bonding pad 306. The method of forming the cover layer 308b includes, for example, but not limited to, the following process. First of all, a patterned photoresist layer having opening 310 (not shown) is formed on the cover layer 308. Next, a portion of the cover layer 308 not covered by the photoresist layer is removed by a dry etching method to form an opening 310, wherein the cover layer 308 in the opening 310 is not totally removed. Thus, the thin cover layer 308 on the surface of the bonding pad 306 is referred to as the cover layer 308a.

Then, referring FIG. 3C, color filters 312 are formed on the cover layer 308b except for the opening 310, in which the color filters 312 include, for example, but not limited to, three different colors (red, blue and green). Moreover, the color filters 312 with different colors are disposed on different photodiode sensing areas 302. The method of forming the color filters 312 includes, for example, but not limited to, the following process. First of all, first color filters having a first color (for example, a red color) is formed using a conventional process, the first color filters are constituted with, for example, a dye of the first color (for example, a red color). Secondly, second color filters having a second color (for example, a blue color) are formed, wherein the second color filters are constituted with, for example, a dye of the second color (for example, a blue color). Finally, third color filters having a third color (for example, a green color) are formed, wherein the third color filters are constituted with, for example, a dye of the third color (for example, a green color).

Then, referring FIG. 3D, a patterned planarization layer 314 is formed on the color filters 312 and the cover layer 308b in order to planarize the surface of the color filters 312, wherein the opening 310 remain exposed. The material of the planarization layer 314 includes, for example, but not limited to, a transparent material such as a transparent polymer.

It is to be understood that the advantage of having a thin cover layer 308a on the surface of the bonding pad 306 is to protect the bonding pad from the corrosive chemicals of the photoresist and the developer. Therefore the surface of the bonding pad 306 is unaffected during the process of forming the color filters 312 and the planarization layer 314.

Next, referring FIG. 3E, the cover layer 308a in the opening 310 is removed in order to expose the surface of the bonding pad 306. The method of removing the cover layer 308a includes, for example, but not limited to, a dry etching method. Likewise, since the process of removing the cover layer 308a is performed after forming the planarization layer 314, and therefore damage to the color filters 312 due the removing process process can be effectively avoided.

Moreover, the material of the above cover layer 308a can be selected so that it can be more easily removed during the removing process, so that damage to the color filters 312 or the planarization layer 314 the during the removing process can be substantially reduced or prevented.

In addition, the advantage of having the thin cover layer 308a on the bonding pad 306 is that the cover layer 308a can be easily removed. Thus the damage to the color filters 312 and the planarization layer 314 during the removing process of the cover layer 308a can also be substantially reduced or prevented.

Then, referring FIG. 3F, a plurality of micro lenses 316 are formed on the planarization layer 314, wherein the micro lenses 316 correspond to different color filters 312 respectively. The micro lenses 316 can focus and project the incident light of the image into the photodiode sensing areas 302 disposed on the surface of the image sensor device. The material of the micro lenses 316 includes, for example, but not limited to, a highly transparent photoresist material, such as a positive photoresist. The method of forming the micro lenses 316 includes, for example, but not limited to the following steps. First of all, the above photoresist material is coated on the planarization layer 314. Secondly, an exposure and a development processes are performed to form a plurality of photoresist patterns over each of the pixels, i.e., the photodiode sensing areas 302. Thirdly, a thermal process performed to transform the photoresist pattern into convex micro lenses 316 having a focusing function. Thus, the fabrication of the image sensor device of the present invention is completed.

Moreover, in the above embodiments, the cover layer 220 (308a) is removed after the planarization layer 214 (314) is patterned, and before the micro lenses 216 (316) are formed. Thus, the damage to the color filters 212 (312) and the planarization layer 214 (314) during the process of removing the cover layer 220 (308a) can be substantially reduced or prevented. However, the present invention is not limited in these two embodiments, i.e., for example, the process of forming the cover layer 220 (308a) of the present invention is not limited in the process of the above embodiments. The process of removing the cover layer 220 (308a), can also be performed after the micro lenses 216 (316) is completely formed, preferably after the photoresist pattern is formed, and before the thermal process is performed.

Accordingly, in the process of manufacturing the image sensor device of the invention, the surface of the bonding pad is protected by the thin cover layer so that damage of the surface of the bonding pad due to the chemicals used in the process of forming the color filters and micro lenses can be effectively avoided. Thus the wiring process can be reliably carried out.

Moreover, since the process of removing the cover layer over the surface of the bonding pad can be performed after forming the planarization layer, therefore the color filters can be completely protected during the process of removing the cover layer.

In addition, since the process of removing the cover layer over the surface of the bonding pad can also be performed after forming the micro lenses 216 (316), preferably after forming the photoresist pattern, and before performing the thermal process, and therefore damage of the surface of the bonding pad can be further protected from chemicals used for forming the micro lenses. Moreover, the damage of the micro lenses during the process of removing the cover layer can also be reduced or prevented.

Moreover, since the thickness of the cover layer formed on the surface of the bonding pad is thin, and therefore the cover layer can be easily removed. Thus, the damage on the color filters and the planarization layer during the removing process can be substantially reduced or prevented.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A manufacturing method of an image sensor device, suitable for a substrate having at least one bonding pad, a plurality of photodiode sensing areas are formed on the substrate, at least a dielectric layer is formed over the substrate, wherein the bonding pad is disposed in the dielectric layer, wherein a first cover layer having an opening is disposed over the dielectric layer, and wherein a portion of a surface of the bonding pad is exposed within the opening, the manufacturing method comprising:
forming a second cover layer over the first cover layer and the opening;
forming a plurality of color filters on the second cover layer;
forming a planarization layer on the second cover layer and the color filters; and
forming a plurality of micro lenses on the planarization layer.

2. The manufacturing method of an image sensor device of claim 1, further comprising:
removing a portion of the second cover layer in the opening after the step of forming the planarization layer on the second cover layer and the color filters, and before the step of forming the micro lenses on the planarization layer.

3. The manufacturing method of an image sensor device of claim 2, wherein the step of removing the second cover layer comprises a dry etching method.

4. The manufacturing method of an image sensor device of claim 1, wherein the step of forming the micro lenses comprises:
forming a micro lens material layer on the planarization layer;
patterning the micro lens material layer for forming a plurality of micro lenses patterns; and
performing a thermal process on the micro lens patterns for forming the micro lenses.

5. The manufacturing method of an image sensor device of claim 4, further comprising:
removing a portion of the second cover layer in the opening after the step of patterning the micro lens material layer and before the step of performing the thermal process on the micro lens patterns.

6. The manufacturing method of an image sensor device of claim 5, wherein the step of removing a portion of the second cover layer in the opening comprises a dry etching method.

7. The manufacturing method of an image sensor device of claim 1, wherein the second cover layer is comprised of a silicon oxide.

8. The manufacturing method of an image sensor device of claim 1, wherein the second cover layer is comprised of a silicon nitride.

9. The manufacturing method of an image sensor device of claim 1, wherein a thickness of the second cover layer is in a range of about 25 nm to about 50 nm.

10. A manufacturing method of an image sensor, suitable for a substrate having at least one bonding pad, wherein a plurality of photodiode sensing areas are formed on the substrate, wherein at least a dielectric layer is formed over the substrate, and wherein the bonding pad is disposed in the dielectric layer, the manufacturing method comprising:
forming a cover layer on the dielectric layer;
patterning the cover layer to form an opening in a first portion of the cover layer on the bonding pad, and retaining a second portion of the cover layer in the opening for covering a portion of the surface of the bonding pad;
forming a plurality of color filters on the cover layer;
forming a planarization layer on the cover layer and the color filters; and
forming a plurality of micro lenses on the planarization layer.

11. The manufacturing method of an image sensor device of claim 10, further comprising:
removing the remaining portion of the cover layer in the opening, after the step of forming the planarization layer on the cover layer and the color filters and before the step of forming the micro lenses on the planarization layer.

12. The manufacturing method of an image sensor device of claim 11, wherein the step of removing the remaining portion of the cover layer in the opening comprises a dry etching method.

13. The manufacturing method of an image sensor device of claim 10, wherein step of forming the micro lenses comprises:
forming a micro lens material layer on the planarization layer;
patterning the micro lens material layer for forming a plurality of micro lens patterns; and
performing a thermal process on the micro lens patterns for forming the micro lenses.

14. The manufacturing method of an image sensor device of claim 13, further comprising:
removing the remaining portion of the cover layer in the opening, after the step of patterning the micro lens material layer for forming the micro lens patterns and before the step of performing the thermal process on the micro lens patterns.

15. The manufacturing method of an image sensor device of claim 14, wherein step of removing the remaining portion of the cover layer in the opening comprises a dry etching method.

16. The manufacturing method of an image sensor device of claim 10, wherein the cover layer is comprised of a silicon nitride.

17. A manufacturing method of an image sensor device, suitable for a substrate having at least one bonding pad, a plurality of photodiode sensing areas are formed on the substrate, at least a dielectric layer formed over the substrate, wherein the bonding pad is disposed in the dielectric layer, wherein a first cover layer having an opening is disposed over the dielectric layer and wherein a surface of the bonding pad within the opening, the method comprising:
forming a second cover layer over the opening covering the exposed surface of the bonding pad;
forming a plurality of color filters on the first cover layer;
forming a planarization layer on the first cover layer and the color filters; and
forming a plurality of micro lenses on the planarization layer.

18. The manufacturing method of an image sensor device of claim 17, further comprising:
removing a portion of the second cover layer formed on the surface of the bonding pad after the step of forming the planarization layer on the first cover layer and the color filters and before the step of forming the micro lenses on the planarization layer.

19. The manufacturing method of an image sensor device of claim 17, wherein the step of forming the micro lenses comprises:
forming a micro lens material layer on the planarization layer;
patterning the micro lens material layer for forming a plurality of micro lens patterns; and
performing a thermal process on the micro lens patterns for forming the micro lenses.

20. The manufacturing method of an image sensor device of claim 19, further comprising:
removing the portion of the second cover layer on the surface of the bonding pad after the step of patterning the micro lens material layer for forming the micro lens patterns and before the step of proceeding the thermal process on the micro lens patterns.
